(19) United States
(12) Patent Application Publication
(10) Pub. No.: US 2026/0372037 A1
(43) Pub. Date: Nov. 19, 2026

(54) SEMICONDUCTOR DEVICE

(71) Applicants: Kabushiki Kaisha Toshiba, Kawasaki-shi (JP); Toshiba Electronic Devices & Storage Corporation, Kawasaki-shi (JP)

(72) Inventors: Hideki SEKIGUCHI, Yokohama Kanagawa (JP); Akira YOSHIOKA, Yokohama Kanagawa (JP); Toru SUGIYAMA, Musashino Tokyo (JP); Yasuhiro ISOBE, Narashino Chiba (JP); Hitoshi KOBAYASHI, Yamato Kanagawa (JP)

(21) Appl. No.: 19/477,272

(22) PCT Filed: Sep. 20, 2023
(86) PCT No.: PCT/JP2023/034094

§ 371 Date: Oct. 21, 2025

(51) Int. Cl. H10W 10/20; H10D 30/47; H10D 62/824; H10D 64/00; H10D 84/87; H10W 10/10

(52) U.S. Cl. CPC H10W 10/20; H10D 30/475; H10D 84/87; H10W 10/181; H10D 62/824; H10D 64/111

(57) ABSTRACT

[Object] To provide a semiconductor device having a small output capacitance.

[Solving Means] According to the present embodiment, a semiconductor device, according to the present embodiment, a semiconductor device includes a substrate, a first nitride semiconductor layer, a second nitride semiconductor layer, a first electrode, a second electrode, and a third electrode. The first nitride semiconductor layer is located on the substrate. The second nitride semiconductor layer is a nitride semiconductor layer located on the first nitride semiconductor layer and having a bandgap larger than that of the first nitride semiconductor layer. The first electrode is located on the second nitride semiconductor layer. The second electrode is located on the second nitride semiconductor layer. The third electrode is located on the second nitride semiconductor layer between the first electrode and the second electrode. The substrate is configured according to a position of the second electrode and has at least either a first insulating layer or a first air layer being a region lower in permittivity than the substrate.

### FIELD

The embodiments of the present invention relate to a semiconductor device.

### BACKGROUND

It is known that a semiconductor device such as a transistor or a diode using a nitride semiconductor has a higher operating frequency and a higher current density than conventional semiconductor devices.

### CITATION LIST

### Patent Literature

Patent Literature 1: Japanese Patent Application Laid-open No. 2011-204984

### SUMMARY

### Technical Problem

An object to be solved by the present invention is to provide a semiconductor device having a small output capacitance.

### Solution to Problem

According to the present embodiment, a semiconductor device includes a substrate, a first nitride semiconductor layer, a second nitride semiconductor layer, a first electrode, a second electrode, and a third electrode. The first nitride semiconductor layer is located on the substrate. The second nitride semiconductor layer is a nitride semiconductor layer located on the first nitride semiconductor layer and having a bandgap larger than that of the first nitride semiconductor layer. The first electrode is located on the second nitride semiconductor layer. The second electrode is located on the second nitride semiconductor layer. The third electrode is located on the second nitride semiconductor layer between the first electrode and the second electrode. The substrate is configured according to a position of the second electrode and has at least either a first insulating layer or a first air layer being a region lower in permittivity than the substrate.

### BRIEF DESCRIPTION OF DRAWINGS

FIG. 1 is a schematic top view of a semiconductor device of the present embodiment.

FIG. 2 is a schematic sectional view of the semiconductor device of the present embodiment.

FIG. 3 is a diagram representing drain-source capacitances.

FIG. 4 is a diagram representing output charge amounts.

FIG. 5 is a schematic top view of a semiconductor device according to a second embodiment.

FIG. 6 is a schematic sectional view of the semiconductor device according to the second embodiment.

FIG. 7 is a schematic sectional view of a semiconductor device according to a third embodiment.

FIG. 8 is a schematic top view of a first configuration example of a semiconductor device according to a fourth embodiment.

FIG. 9 is a schematic top view of a second configuration example of the semiconductor device according to the fourth embodiment.

FIG. 10 is a schematic top view of a third configuration example of the semiconductor device according to the fourth embodiment.

### DESCRIPTION OF EMBODIMENTS

Embodiments of the present invention will now be explained below with reference to the drawings. In the following embodiments, while characteristic configurations and operations of a semiconductor device will be explained, configurations and operations omitted in the following descriptions may be included in the semiconductor device.

### First Embodiment

Embodiments of the present invention will be explained below with reference to the drawings. The drawings are schematic and conceptual, and the relation between the thickness and the width of each part, the ratio of size among the parts, and the like do not necessarily match those of actual products. Even in a case where the same parts are represented, the dimensions and the ratios thereof are represented differently depending on the drawings in some cases. In the specification of the present application and the respective drawings, the same elements as those already explained are denoted by like reference characters and detailed explanations thereof are omitted as appropriate.

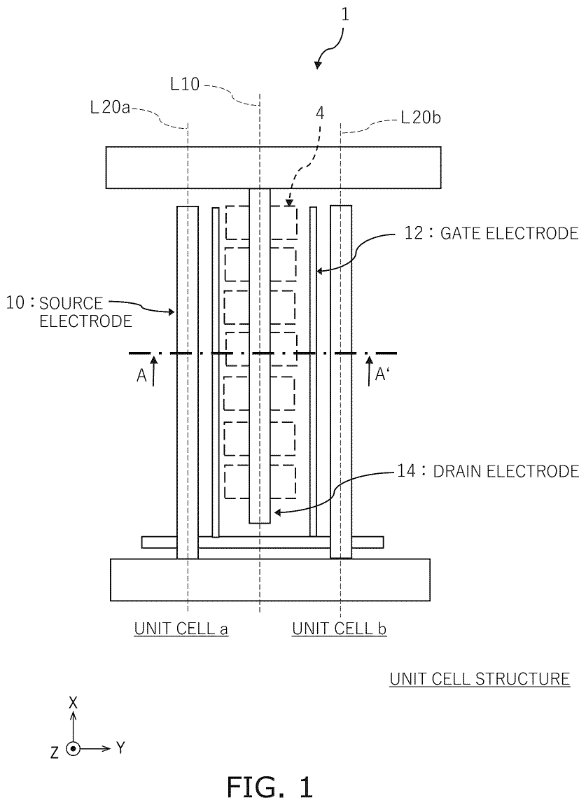

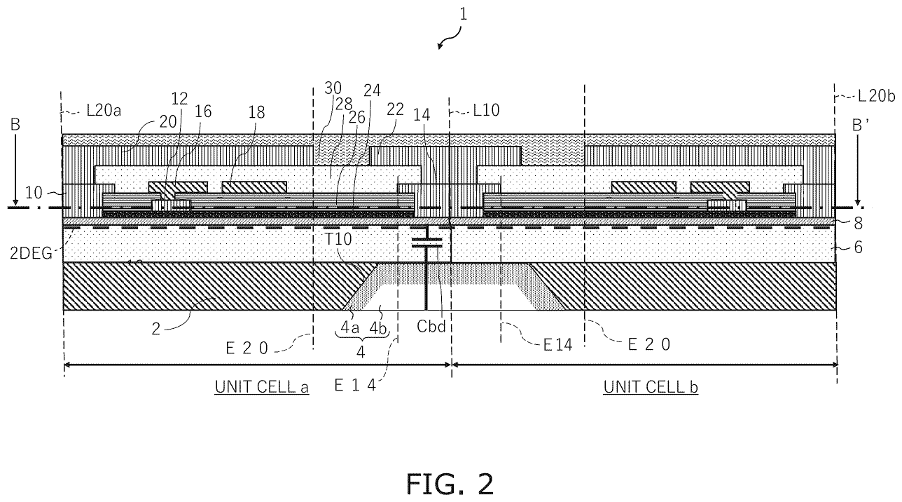

FIG. 1 is a schematic top view of a semiconductor device 1 of the present embodiment. FIG. 2 is a schematic sectional view of the semiconductor device 1 of the present embodiment. FIG. 2 is a sectional view along a line A-A′ in FIG. 1. FIG. 1 is a top view in a section along a line B-B′ in FIG. 2.

This semiconductor device 1 is, for example, a HEMT (High Electron Mobility Transistor) using a nitride semiconductor such as GaN (gallium nitride), AlGaN (aluminum gallium nitride), or InGaN (indium gallium nitride). The semiconductor device 1 according to the present embodiment has a transverse device structure using a nitride semiconductor. The electrode structure of the semiconductor device 1 according to the present embodiment is, for example, a multi-finger structure. As illustrated in FIG. 1, a unit cell a and a unit cell b are arranged in a y-direction symmetrically about a line L10.

The semiconductor device 1 includes a substrate 2, a first insulating layer 4, a first nitride semiconductor layer 6, a second nitride semiconductor layer 8, source electrodes (one example of a first electrode) 10, gate electrodes (one example of a third electrode) 12, a drain electrode (one example of a second electrode) 14, gate field-plate electrode parts 16, field-plate electrode parts 18, source field-plate electrode parts (one example of an electrode part) 20, a drain field-plate electrode part 22, an insulating film 24, a second insulating layer 26, a third insulating layer 28, and a fourth insulating layer 30. In the present embodiment, an X-direction, a Y-direction perpendicularly intersecting with the X-direction, and a Z-direction perpendicularly intersecting with the X-direction and the Y-direction are defined. The Z-direction is a direction in which the first insulating layer 4, the first nitride semiconductor layer 6, and the second nitride semiconductor layer 8 are stacked. In some cases, an upper direction in the drawings of the present specification is described as “upper” and a lower direction in the drawings is described as “lower”. In the present specification, the concepts of “upper” and “lower” are not necessarily terms representing a relation with the direction of gravity.

An output capacitance Coss of the semiconductor device 1 is the sum of a drain-source capacitance Cds and a gate-drain capacitance Cgd. A capacitance component between the substrate 2 and the first insulating layer 4, and the drain electrode 14, and a capacitance component between a package provided under the substrate 2 and the first insulating layer 4, and the drain electrode 14 greatly contributes to the drain-source capacitance Cds.

Each of end lines E14 is a line perpendicular to the lower surface of the first nitride semiconductor layer 6 along an end portion of the drain electrode 14 on the side of a source electrode 10. Each of end lines E20 is a line perpendicular to the lower surface of the first nitride semiconductor layer 6 along an end portion of a source field-plate electrode part 20 at a portion extending along the third insulating layer 28 on the side of the drain electrode 14.

As the substrate 2, a Si (silicon) substrate or a sapphire substrate is used, for example. Preferably, the substrate 2 is a Si (silicon) substrate. The range of the substrate 2 in the Y-direction is set to a range based on the end lines E20 of the source field-plate electrode parts 20 on the side of the drain electrode 14, which will be described later. Preferably, a range to positions nearer the drain electrode 14 beyond the end lines E20 is the range of the substrate 2 in the Y-direction. For example, a boundary surface between the substrate 2 and the first insulating layer 4 is configured in a range between each of the end lines E14 and the corresponding end line E20. This enables an electric field relaxation function of the source field-plate electrode parts 20 to be maintained.

The first insulating layer 4 is constituted of a material lower in permittivity than the substrate 2. The first insulating layer 4 is constituted as a part of the region of the substrate 2 and includes a first insulating layer 4a and a first insulating layer 4b. The first insulating layer 4a is, for example, an insulating layer such as PI or a resin. More specifically, for example, organic SOG, hydrogen silsesquioxane, or poly(arylene ether) can be used as a coating material. As a film according to a CVD method, a methylsilane CVD film may be used, for example. Alternatively, organic SOG having pores, hydrogen silsesquioxane having pores, poly(arylene ether) having pores, or a methylsilane CVD film having pores may be used.

The first insulating layer 4b is constituted of a material lower in permittivity than the substrate 2. Similarly to the first insulating layer 4a, the first insulating layer 4b is, for example, organic SOG, hydrogen silsesquioxane, poly(arylene ether), a methylsilane CVD film, or air. Alternatively, the first insulating layer 4b may be organic SOG having pores, hydrogen silsesquioxane having pores, poly(arylene ether) having pores, or a methylsilane CVD film having pores.

The range of the upper surface of the first insulating layer 4 in the Y-direction is set to a range based on the end lines E14 of the drain electrode 14 on the side of the source electrodes 10. As described above, the boundary surface between the substrate 2 and the first insulating layer 4 is configured in the range between each of the end lines E14 and the corresponding end line E20. That is, the range of the substrate 2 and the first insulating layer 4 is set considering the electric field relaxation function of the source field-plate electrode parts 20 and reduction of the drain-source capacitance Cds.

The first insulating layer 4 has a structure in which the range in the Y-direction enlarges with the distance from the lower surface of the first nitride semiconductor layer 6. That is, the boundary surface of the first insulating layer 4 with the substrate 2 is configured to have a sloped surface T10. Accordingly, the drain-source capacitance Cds can be reduced while the influence on the electric field relaxation function of the source field-plate electrode parts 20 is decreased. In this example, the capacitance between the drain electrode 14 and the bottom surface of the first insulating layer 4 is Cbd. That is, the capacitance Cbd is included in capacitance components of the drain-source capacitance Cds. Details of the capacitance Cbd will be described later.

The first nitride semiconductor layer 6 is provided on the substrate 2 and on the first insulating layer 4. The first nitride semiconductor layer 6 is, for example, undoped Al_{X}Ga_{1-X}N (0≤X<1). More specifically, the first nitride semiconductor layer 6 is, for example, undoped GaN. The first nitride semiconductor layer 6 functions as a channel layer. The thickness of the first nitride semiconductor layer 6 is, for example, not less than 1 μm and not more than 10 μm.

The second nitride semiconductor layer 8 is provided on the first nitride semiconductor layer 6. The bandgap of the second nitride semiconductor layer 8 is configured to be larger than that of the first nitride semiconductor layer 6. The second nitride semiconductor layer 8 is, for example, undoped Al_{Y}Ga_{1-Y}N (0<Y≤1, X<Y). More specifically, the second nitride semiconductor layer 8 is, for example, undoped Al_{0.2}Ga_{0.8}N. The second nitride semiconductor layer 8 functions as a barrier layer. The thickness of the second nitride semiconductor layer 8 is, for example, 15 nm to 50 nm and is preferably 30 nm.

A heterojunction interface is provided between the first nitride semiconductor layer 6 and the second nitride semiconductor layer 8. At the time of an on-operation of the semiconductor device 1, two-dimensional electron gas (2DEG) is formed on the heterojunction interface and becomes carriers. The substate 2, the first insulating layer 4, the first nitride semiconductor layer 6, and the second nitride semiconductor layer 8 are arranged in parallel to a plane including an X-axis parallel to the X-direction and a Y-axis parallel to the Y-direction, that is, an X-Y plane. An interface between the substrate 2 and the first nitride semiconductor layer 6, an interface between the first insulating layer 4 and the first nitride semiconductor layer 6, and an interface between the first nitride semiconductor layer 6 and the second nitride semiconductor layer 8 are provided in parallel to the X-Y plane. The Y-direction is a direction in which the carriers of the semiconductor device 1 being a HEMT flow. In other words, the Y-direction is the gate length direction of the semiconductor device 1. The X-direction is the gate width direction of the semiconductor device 1.

The source electrodes 10 are provided on the second nitride semiconductor layer 8. The source electrodes 10 function as a source electrode of the semiconductor device 1. Each of the source electrodes 10 is configured, for example, to include a stacked structure of titanium (Ti) and aluminum (Al).

The drain electrode 14 is provided on the second nitride semiconductor layer 8. The drain electrode 14 functions as a drain electrode of the semiconductor device 1. The drain electrode 14 is configured, for example, to include a stacked structure of titanium (Ti) and aluminum (Al). The distance between each of the source electrodes 10 and the drain electrode 14 is, for example, not less than 5 μm and not more than 30 μm.

The insulating film 24 is provided between each of the source electrodes 10 and the drain electrode 14 on the second nitride semiconductor layer 8. The insulating film 24 is in direct contact with the second nitride semiconductor layer 8. The insulating film 24 is configured to include an insulating material. For example, the insulating material is silicon nitride (SiN). However, the material included in the insulating film 24 is not limited thereto. For example, the insulating material may be silicon oxide (SiO), silicon oxynitride (SiON), silicon oxide containing carbon (SiOC), aluminum nitride (AlN), or aluminum oxide (AIO). The thickness of the insulating film 24 in the Z-direction is, for example, 20 nm to 30 nm.

Each of the gate electrodes 12 is provided on the second nitride semiconductor layer 8 between a source electrode 10 and the drain electrode 14. More specifically, each of the gate electrodes 12 is provided on the insulating film 24 between the second nitride semiconductor layer 8 and the second insulating layer 26. Each of the gate electrodes 12 includes, for example, a stacked structure of nickel (Ni) and gold (Au), (TiN), or polycrystalline silicon (Poly-Si). It is titanium nitride preferable that the bottom surfaces of the gate electrodes 12 are in contact with the insulating film 24.

The second insulating layer 26 is provided on the gate electrodes 12 on the insulating film 24. The second insulating layer 26 is configured, for example, to include silicon nitride (SiN). However, the material included in the second insulating layer 26 is not limited thereto. For example, the second insulating layer 26 may be configured to include silicon oxide (SiO), silicon oxynitride (SiON), silicon oxide containing carbon (SiOC), or aluminum nitride (AlN), aluminum oxide (AIO). The thickness of the second insulating layer 26 in the Z-direction is, for example, 200 nm to 300 nm.

Each of the gate field-plate electrode parts 16 has a portion extending along the upper surface of the second insulating layer 26 and has one end electrically connected to a gate electrode 12. That is, one end of the gate field-plate electrode part 16 is electrically connected to the upper surface of the gate electrode 12. The gate field-plate electrode parts 16 extend upward in the second insulating layer 26 and extend in the gate length direction on the second insulating layer 26. However, the form of the gate field-plate electrode parts 16 is not limited thereto. The gate field-plate electrode parts 16 are used to relax the electric field in the semiconductor device 1. Each of the gate field-plate electrode parts 16 is, for example, a structure including a stacked structure of Al (aluminum), Cu (copper), W (tungsten), and TIN (titanium nitride) or a stacked structure of titanium (Ti) and aluminum (Al).

Each of the field-plate electrode parts 18 has a portion extending along the upper surface of the second insulating layer 26 between a gate field-plate electrode part 16 and the drain electrode 14. That is, the field-plate electrode part 18 is provided on the second insulating layer 26 between the insulating film 24 and the third insulating layer 28. Each of the field-plate electrode parts 18 is electrically connected to, for example, a source electrode 10 using, for example, a line (not illustrated) provided in the gate width direction. The field-plate electrode parts 18 are used to relax the electric field in the semiconductor device 1. Each of the field-plate electrode parts 18 is, for example, a structure including a stacked structure of Al (aluminum), Cu (copper), W (tungsten), and TiN (titanium nitride) or a stacked structure of titanium (Ti) and aluminum (Al).

The third insulating layer 28 is provided on the second insulating layer 26, on the gate field-plate electrode parts 16, and on the field-plate electrode parts 18. The third insulating layer 28 is configured to include, for example, silicon dioxide (SiO₂) being silicon oxide. Alternatively, the third insulating layer 28 may be configured to include silicon monoxide (SiO) being silicon oxide, silicon oxynitride (SiON), silicon oxide containing carbon (SiOC), aluminum nitride (AlN), aluminum oxide (AIO), or the like. However, the material included in the third insulating layer 28 is not limited thereto.

Each of the source field-plate electrode parts 20 has one end electrically connected to a source electrode 10, and has a portion extending on a gate field-plate electrode part 16 and on a field-plate electrode part 18 along the upper surface of the second insulating layer 26. That is, one end of the source field-plate electrode part 20 is provided, for example, on the corresponding source electrode 10 and is electrically connected to the source electrode 10. The source field-plate electrode parts 20 are provided on the source electrodes 10, on the gate electrodes 12, on the gate field-plate electrode parts 16, on the field-plate electrode parts 18, on the insulating film 24, and on the third insulating layer 28 between the second insulating layer 26 and the fourth insulating layer 30. The source field-plate electrode parts 20 are used to relax the electric field in the semiconductor device 1. Each of the source field-plate electrode parts 20 is, for example, a structure including a stacked structure of Al (aluminum), Cu (copper), W (tungsten), and TiN (titanium nitride) or a stacked structure of titanium (Ti) and aluminum (Al).

The drain field-plate electrode part 22 has a portion with one end electrically connected to the drain electrode 14 and extending along the upper surface of the insulating film 24. That is, the drain field-plate electrode part 22 is electrically connected to the drain electrode 14. One end of the drain field-plate electrode part 22 is, for example, provided on the drain electrode 14 and is electrically connected to the upper surface of the drain electrode 14. The drain field-plate electrode part 22 extends, for example, to the side of the source electrodes 10. The drain field-plate electrode part 22 is provided, for example, on the third insulating layer 28. The drain field-plate electrode part 22 is used to relax the electric field in the semiconductor device 1. The drain field-plate electrode part 22 is, for example, a structure including a stacked structure of Al (aluminum), Cu (copper), W (tungsten), and TIN (titanium nitride) or a stacked structure of titanium (Ti) and aluminum (Al).

Effects of the capacitance Cbd are described below. The drain-source capacitance Cds including the capacitance Cbd is approximately represented by an expression (1). Minute ΔSₙ denotes an area having a minute width in the Y-direction of the lower surface of the substrate 2 and the first insulating layer 4. A permittivity εₙ is a capacitance between ΔSₙ and the drain electrode 14 and a distance dₙ is a distance between ΔSₙ and the drain electrode 14. In this expression, n=1 indicates the position of ΔS₁ being in contact with the line L10 as an end portion of the drain electrode 14, and n=m indicates the position of εₘ being in contact with a line L20a as an end portion of the substrate 2 on the side of a source electrode 10. That is, as for the distance dₙ, d₁ is the shortest and dm is the longest.

### [Expression 1]

$$Cds = {\sum }_{n = 1}^{n - m} ( {ε}_{n} \frac{Δ {S}_{n}}{{d}_{n}} ) \qquad ( 1 )$$

As indicated by the expression (1), the capacitance Cds has a greater influence as the distance dₙ is smaller when minute ΔSₙ is the same. Accordingly, in the present embodiment, the permittivity εₙ (mb≥n) of the distance dₙ in a predetermined range, for example, a range of n≤mb is constituted to be smaller than the permittivity εₙ (m≥n>mb) in a range of n>mb. That is, mb is less than m.

Referring back to FIG. 1, since a cross section (a Z-Y plane) of the first insulating layer 4 has a trapezoidal shape having the sloped surface T10, the range of the permittivity εₙ (mb≥n) can be elongated along the distance dₙ (mb≥n) and the capacitance Cbd can be effectively reduced. Since the cross section has a trapezoidal shape with the sloped surface T10, the range of the upper surface of the substrate 2 can be constituted to be wider and the electric field relaxation function of the source field-plate electrode parts 20 can be more efficiently maintained. As described above, since the cross section (the Z-Y plane) of the first insulating layer 4 is trapezoid-shaped having the sloped surface T10, the drain-source capacitance Cds can be more efficiently reduced while the electric field relaxation function of the source field-plate electrode parts 20 is maintained.

The capacitance Cdb between the bottom surface of the first insulating layer 4 and the drain electrode 14 can be represented by an expression (2). As is understood from the above descriptions, as the permittivity εₙ (mb≥n) of the range is decreased, the output capacitance Coss of the semiconductor device 1 can be reduced more.

### [Expression 2]

$$Cdb = {\sum }_{n = 1}^{n - mb} ( {ε}_{n} \frac{Δ {S}_{n}}{{d}_{n}} ) \qquad ( 2 )$$

In this expression, a relation mb<m holds. While the drain-source capacitance Cds represented by the expression (1) can be also reduced by increasing the thickness of the first nitride semiconductor layer 6, warpage and cracks of the substrate 2 occur and the reduction is limited.

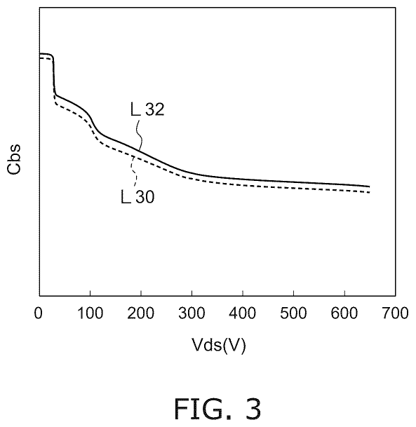

FIG. 3 is a diagram representing the drain-source capacitances Cds in a case where the first insulating layer 4 is included and a case where the first insulating layer 4 is not included. The horizontal axis represents a voltage between the drain electrode 14 and the source electrode 10, and the vertical axis represents a logarithmically converted drain-source capacitance Cds (a freely-selected unit). FIG. 3 is a diagram representing simulation results. The drain-source capacitance Cds in the case where the first insulating layer 4 is included is shown by a line L10 and the drain-source capacitance Cds in the case where the first insulating layer 4 is not included is shown by a line L12. As represented in FIG. 3, the drain-source capacitance Cds in the case where the first insulating layer 4 is included is smaller.

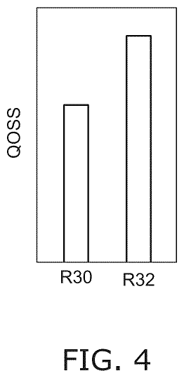

FIG. 4 is a diagram representing output charge amounts QOSS. An output charge amount QOSS in a case where the first insulating layer 4 is included is shown by R10 and an output charge amount QOSS in a case where the first insulating layer 4 is not included is shown by R12. FIG. 4 is a diagram representing simulation results. The output charge amounts QOSS represented in FIG. 4 are charge amounts for charging the output capacitance Coss. In this example, the voltage between the drain electrode 14 and the source electrode 10 is 400 volts. As represented in FIG. 4, the output charge amount QOSS in the case where the first insulating layer 4 is included is about 70 percent of the output charge amount QOSS in the case where the first insulating layer 4 is not included.

In a high-frequency operation, switching loss due to charging and discharging of the output capacitance Coss increases as the output charge amount QOSS increases. Since the semiconductor device 1 according to the present embodiment has the first insulating layer 4, the output charge amount QOSS can be reduced as represented in FIGS. 3 and 4 and the switching loss can be decreased. Accordingly, the semiconductor device 1 having a higher breakdown field intensity and a higher electron mobility can be configured.

As described above, according to the present embodiment, the substrate 2 of the semiconductor device 1 of the present embodiment is configured according to the position of the drain electrode 14 and includes the first insulating layer 4 being lower in permittivity than the substrate 2. This enables the drain-source capacitance Cds to be reduced, and the output capacitance Coss of the semiconductor device 1 can be reduced.

### Second Embodiment

The semiconductor device 1 according to a second embodiment is different from the semiconductor device 1 according to the first embodiment in that a first insulating layer 4c is configured to be divided into a plurality of regions. Differences from the semiconductor device 1 according to the first embodiment are described below.

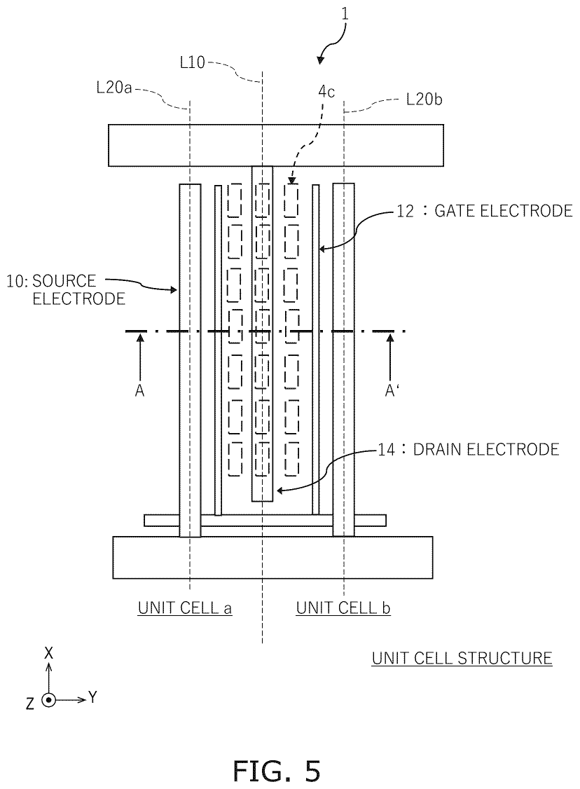

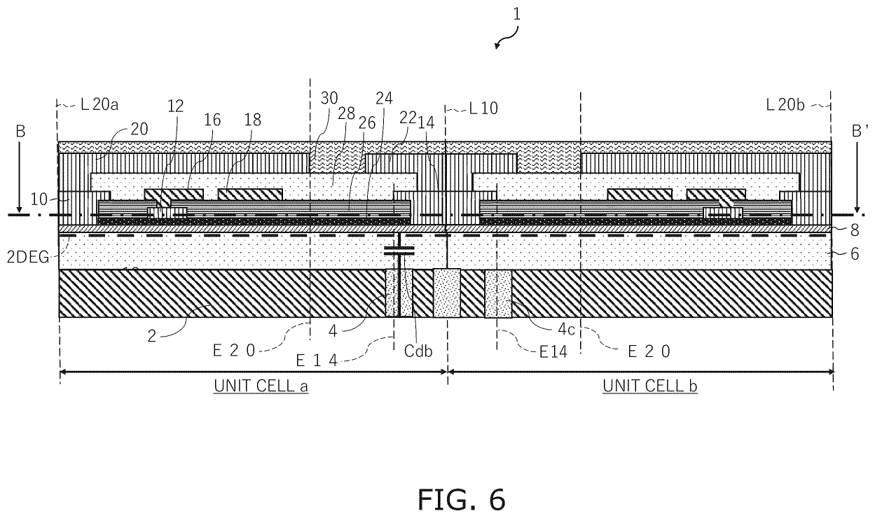

FIG. 5 is a schematic top view of the semiconductor device 1 according to the second embodiment. FIG. 6 is a schematic sectional view of the semiconductor device 1 according to the second embodiment. FIG. 6 illustrates a section along a line A-A′ in FIG. 1. FIG. 5 is a top view in a section along a line B-B′ in FIG. 2.

As illustrated in FIGS. 5 and 6, the semiconductor device 1 according to the second embodiment is different from that according to the first embodiment in that the first insulating layer 4c is configured in the manner of stripes. For example, the first insulating layer 4c is configured to be divided into three regions. That is, the first insulating layer 4c has a plurality of regions divided in the Y-direction parallel to the upper surface of the substrate 2. Each of the divided regions is, for example, a cuboid.

The first insulating layer 4c is constituted of a material lower in permittivity than the substrate 2. The first insulating layer 4c is, for example, an insulating layer of PI or a resin. More specifically, the first insulating layer 4c is, for example, organic SOG, hydrogen silsesquioxane, poly(arylene ether), or a methylsilane CVD film. Alternatively, the first insulating layer 4c may be organic SOG having pores, hydrogen silsesquioxane having pores, poly(arylene ether) having pores, or a methylsilane CVD film having pores. This enables the drain-source capacitance Cds to be reduced. Furthermore, since the substrate 2 and the first insulating layer 4c are alternately configured, reduction in the stiffness of the substrate 2 can be suppressed. Therefore, flatness of the substrate 2 can be maintained.

### Third Embodiment

The semiconductor device 1 according to a third embodiment is different from the semiconductor device 1 according to the first embodiment in that a first insulating layer 4d is configured in the manner of a cuboid. Differences from the semiconductor device 1 according to the first embodiment are described below.

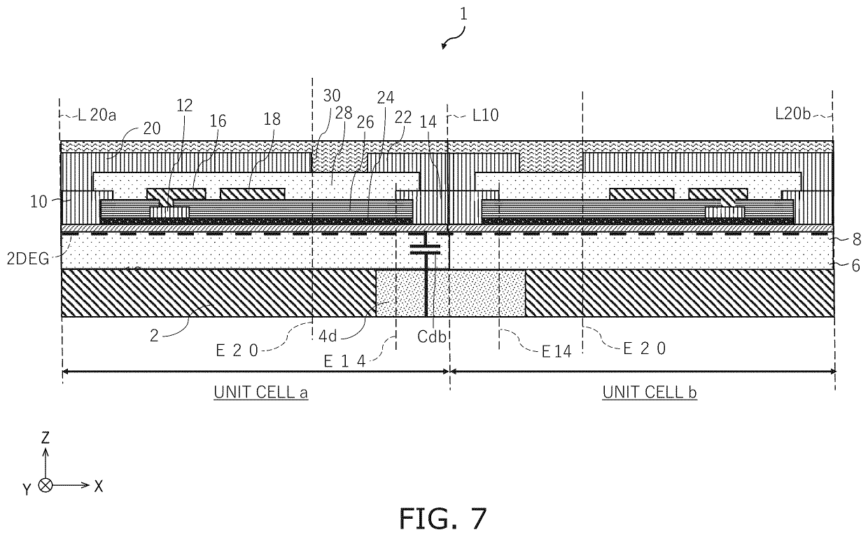

FIG. 7 is a schematic sectional view of the semiconductor device 1 according to the third embodiment. As illustrated in FIG. 7, the semiconductor device 1 according to the third embodiment is different from that according to the first embodiment in that the first insulating layer 4d is configured in the manner of a cuboid. The first insulating layer 4c is configured, for example, to be divided into three regions.

The first insulating layer 4d is constituted of a material lower in permittivity than the substrate 2. The first insulating layer 4d is, for example, an insulating layer of PI or a resin. More specifically, the first insulating layer 4d is, for example, organic SOG, hydrogen silsesquioxane, poly(arylene ether), or a methylsilane CVD film. Alternatively, the first insulating layer 4d may be organic SOG having pores, hydrogen silsesquioxane having pores, poly(arylene ether) having pores, or a methylsilane CVD film having pores. This enables the drain-source capacitance Cds to be reduced. Furthermore, since the first insulating layer 4d is constituted of a single material and in the manner of a cuboid, the film formation process is simplified.

### Fourth Embodiment

The semiconductor device 1 according to a fourth embodiment is different from the semiconductor device 1 according to the first to third embodiments in that a first air layer 4ba, 4ca, or 4da is configured as a hollow wall of the substrate 2. Differences from the semiconductor device 1 according to the first to third embodiments are described below.

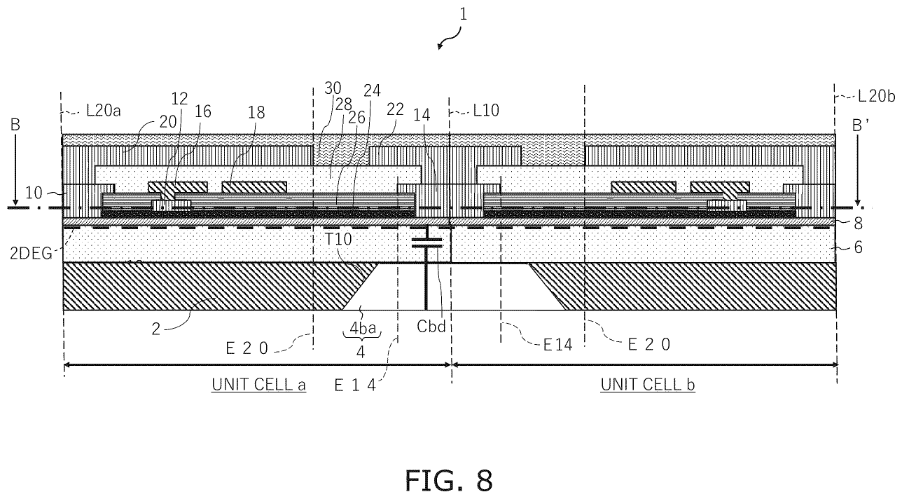

FIG. 8 is a schematic sectional view of a first configuration example of the semiconductor device 1 according to the fourth embodiment. As illustrated in FIG. 8, the semiconductor device 1 according to the fourth embodiment is different from that according to the first embodiment in that the first insulating layers 4a and 4b (see FIG. 2) of the semiconductor device 1 according to the first embodiment are configured as the first air layer 4ba. That is, in the first configuration example of the semiconductor device 1 according to the fourth embodiment, the first air layer 4ba is configured as a hollow wall of the substrate 2. This enables the permittivity of the first air layer 4ba to be decreased more and the output capacitance Coss of the semiconductor device 1 according to the first embodiment can be reduced more.

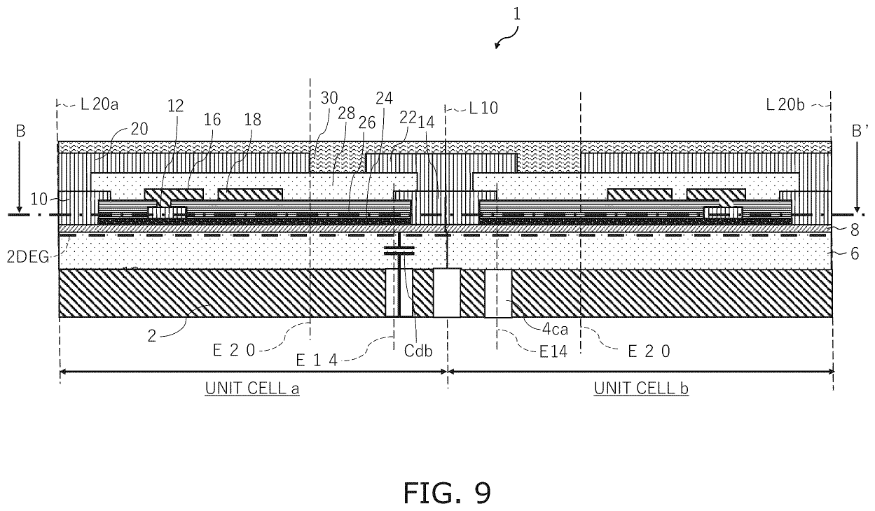

FIG. 9 is a schematic sectional view of a second configuration example of the semiconductor device 1 according to the fourth embodiment. As illustrated in FIG. 9, the semiconductor device 1 according to the fourth embodiment is different from that according to the second embodiment in that the first insulating layer 4c (see FIG. 6) of the semiconductor device 1 according to the second embodiment is configured as the first air layer 4ca. That is, in the second configuration example of the semiconductor device 1 according to the fourth embodiment, the first air layer 4ca is configured as a hollow wall of the substrate 2. This enables the permittivity of the first air layer 4ca to be decreased more and the output capacitance Coss of the semiconductor device 1 according to the second embodiment can be reduced more.

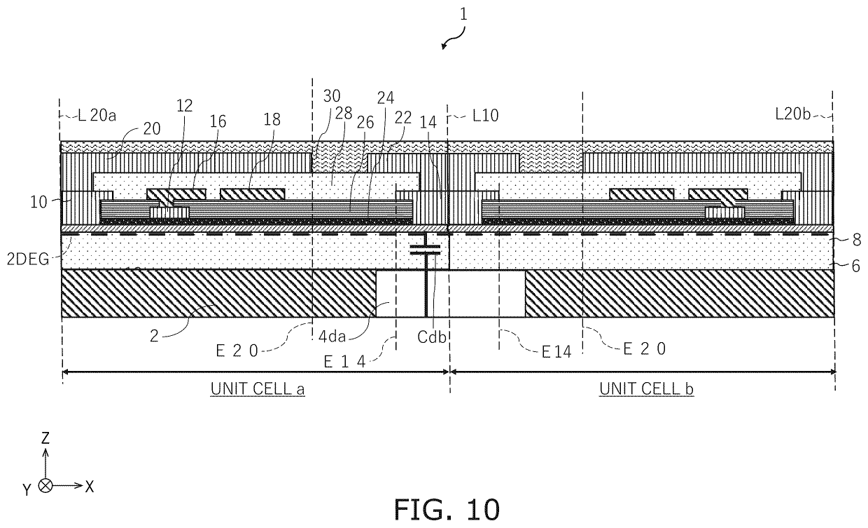

FIG. 10 is a schematic sectional view of a third configuration example of the semiconductor device 1 according to the fourth embodiment. As illustrated in FIG. 10, the semiconductor device 1 according to the fourth embodiment is different from that according to the third embodiment in that the first insulating layer 4d (“see FIG. 7) of the semiconductor device 1 according to the third embodiment is configured as the first air layer 4da. That is, in the third configuration example of the semiconductor device 1 according to the fourth embodiment, the first air layer 4da is configured as a hollow wall of the substrate 2. This enables the permittivity of the first air layer 4da to be decreased more and the output capacitance Coss of the semiconductor device 1 according to the third embodiment can be reduced more.

As described above, according to the present embodiment, the first air layer 4ba, 4ca, or 4da is configured as a hollow wall of the substrate 2. This enables the permittivity of the first air layer 4ba, 4ca, or 4da to be decreased more and the output capacitance Coss of the semiconductor device 1 can be reduced more.

While certain embodiments of the present invention have been described, these embodiments have been presented by way of example only, and are not intended to limit the scope of the invention. The novel embodiments described herein may be embodied in a variety of other forms, and various omissions, substitutions, and changes may be made without departing from the spirit of the invention. These embodiments and modifications thereof would fall within the scope and spirit of the invention, and would fall within the invention described in the accompanying claims and their equivalents.

### REFERENCE SIGNS LIST

1: semiconductor device, 4, 4c, 4d: first insulating layer, 4ba, 4ca, 4da: first air layer, 10: source electrode (one example of first electrode), 12: gate electrode (one example of third electrode), 14: drain electrode (one example of second electrode), 20: source field-plate electrode part (one example of electrode part), 24: insulating film, 26: second insulating layer, E14, E20: end line.

1. A semiconductor device comprising:
a substrate;
a first nitride semiconductor layer located on the substrate;
a second nitride semiconductor layer located on the first nitride semiconductor layer and having a bandgap larger than that of the first nitride semiconductor layer;
a first electrode located on the second nitride semiconductor layer;
a second electrode located on the second nitride semiconductor layer; and
a third electrode located on the second nitride semiconductor layer between the first electrode and the second electrode, wherein
the substrate is configured according to a position of the second electrode and has at least either a first insulating layer or a first air layer being a region lower in permittivity than the substrate.

2. The device of claim 1, wherein at least either the first insulating layer or the first air layer is configured based on a first position where a first direction perpendicular to an upper surface of the first nitride semiconductor layer along an end portion of the second electrode on a side of the first electrode intersects with a lower surface of the first nitride semiconductor layer.

3. The device of claim 2, wherein at least either the first insulating layer or the first air layer has a range enlarging in a direction perpendicular to the first direction and directed from the second electrode toward the first electrode with a distance from the lower surface of the first nitride semiconductor layer along the first direction.

4. The device of claim 3, wherein at least either the first insulating layer or the first air layer has a sloped surface with respect to a direction perpendicular to the first direction and directed from the second electrode toward the first electrode at a boundary with the substrate.

5. The device of claim 4, further comprising an electrode part having one end electrically connected to the first electrode and having a portion extending along an upper surface of the first nitride semiconductor layer on the third electrode.

6. The device of claim 5, wherein the sloped surface is configured according to a position of a second end portion of the extending portion on a side closer to the second electrode.

7. The device of claim 6, wherein at least either the first insulating layer or the first air layer has a boundary with the substrate configured in a range between a second position where a second direction perpendicular to an upper surface of the first nitride semiconductor layer along the second end portion intersects with a lower surface of the first nitride semiconductor layer, and the first position.

8. The device of claim 2, wherein the first insulating layer has a plurality of divided regions in a second direction parallel to an upper surface of the second nitride semiconductor layer and perpendicular to the first direction.

9. The device of claim 8, wherein each of the divided regions is a cuboid.

10. The device of claim 1, wherein at least either the first insulating layer or the first air layer is configured to be flush with an upper surface of the substrate.

11. The device of claim 7, further comprising:
an insulating film located between the first electrode and the second electrode on the second nitride semiconductor layer and being in contact with the second nitride semiconductor layer; and
a second insulating layer located on the insulating film between the first electrode and the third electrode, on the insulating film between the third electrode and the second electrode, and on the third electrode, wherein
the third electrode is located on the insulating film between the first electrode and the second electrode.

12. The device of claim 1, further comprising an electrode part electrically connected to at least any of the first electrode, the second electrode, and the third electrode and arranged above the third electrode.

13. A semiconductor device comprising:
a substrate;
a first nitride semiconductor layer located on the substrate;
a second nitride semiconductor layer located on the first nitride semiconductor layer and having a bandgap larger than that of the first nitride semiconductor layer;
a first electrode located on the second nitride semiconductor layer;
a second electrode located on the second nitride semiconductor layer; and
a third electrode located on the second nitride semiconductor layer between the first electrode and the second electrode, wherein
the substrate is configured according to a position of the second electrode and has a first insulating layer being a region lower in permittivity than the substrate.

14. A semiconductor device comprising:
a substrate;
a first nitride semiconductor layer located on the substrate;
a second nitride semiconductor layer located on the first nitride semiconductor layer and having a bandgap larger than that of the first nitride semiconductor layer;
a first electrode located on the second nitride semiconductor layer;
a second electrode located on the second nitride semiconductor layer; and
a third electrode located on the second nitride semiconductor layer between the first electrode and the second electrode, wherein
the substrate is configured according to a position of the second electrode and has a first air layer being a region lower in permittivity than the substrate.
